(19) United States
(12) Patent Application Publication
(10) Pub. No.: US 2013/0112252 A1
(43) Pub. Date: May 9, 2013

(54) SOLAR CELL AND MANUFACTURING METHOD THEREOF

(71) Applicants: Kyoung-Jin Seo, Yongin-si (KR); Czang-Ho Lee, Yongin-si (KR); Hyun-Jong Kim, Yongin-si (KR); Min Park, Yongin-si (KR); Jun-Ki Hong, Yongin-si (KR); Byong-Gook Jeong, Yongin-si (KR)

(72) Inventors: Kyoung-Jin Seo, Yongin-si (KR); Czang-Ho Lee, Yongin-si (KR); Hyun-Jong Kim, Yongin-si (KR); Min Park, Yongin-si (KR); Jun-Ki Hong, Yongin-si (KR); Byong-Gook Jeong, Yongin-si (KR)

(21) Appl. No.: 13/528,790

(22) Filed: Jun. 20, 2012

(30) Foreign Application Priority Data
Nov. 8, 2011 (KR) 10-2011-0115942

(51) Int. Cl. H01L 31/0352; H01L 31/18; H01L 31/065

(52) U.S. Cl. 136/255; 136/256; 438/72; 257/E31.119

(57) ABSTRACT

A solar cell including a first conductive type semiconductor substrate; a first conductive type first semiconductor layer on a back surface of the semiconductor substrate; a second conductive type second semiconductor layer on the back surface of the semiconductor substrate at a height different from the first semiconductor layer, the second semiconductor layer being separated from the first semiconductor layer; and a passivation layer on the back surface of the semiconductor substrate. The passivation layer covers at least a portion of the first semiconductor layer and at least a portion of the second semiconductor layer. The passivation layer includes impurities.

### CROSS-REFERENCE TO RELATED APPLICATION

This application claims priority to and the benefit of Korean Patent Application No. 10-2011-0115942 filed in the Korean Intellectual Property Office on Nov. 8, 2011, the entire content of which is incorporated herein by reference.

### BACKGROUND

1. Field

The described technology relates generally to a solar cell, and more particularly, to a back contact solar cell and a manufacturing method thereof.

2. Description of Related Art

A back contact electrode solar cell has a structure in which all of a p-type semiconductor layer, a first electrode connected therewith, an n-type semiconductor layer, and a second electrode connected therewith, are disposed on a back surface of a solar cell that is an opposite surface of a light receiving surface. In the structure, a metal electrode is not positioned on the light receiving surface of the solar cell and thus, degradation in solar absorption due to the metal electrode may be prevented.

However, in the back contact solar cell, deposition, mask disposition, drive in diffusion (doping), and patterning processes need to be repeated twice so as to form a p-type semiconductor layer and an n-type semiconductor layer, and as a result, the whole process is relatively complicated.

In particular, an impurity doping process, which is a high temperature process of, for example, approximately 900° C. or more, is a process that consumes a considerable amount of energy. Further, the impurity doping process needs to be repeated twice and, therefore, the manufacturing cost is increased. Further, a junction may be formed in an undesired direction during the impurity doping process, and it is difficult to uniformly dope trivalent impurities at the time of forming the p-type semiconductor layer.

The above information disclosed in this Background section is only for enhancement of understanding of the background of the described technology and therefore it may contain information that does not form the prior art that is already known in this country to a person of ordinary skill in the art.

### SUMMARY OF THE INVENTION

Aspects of the described technology provide a solar cell and a manufacturing method thereof capable of simplifying a manufacturing process, preventing junction defects, and easily forming a p-type semiconductor layer.

An exemplary embodiment of the present invention includes a solar cell including a first conductive type semiconductor substrate; a first conductive type first semiconductor layer on a back surface of the semiconductor substrate; a second conductive type second semiconductor layer on the back surface of the semiconductor substrate at a height different from the first semiconductor layer, the second semiconductor layer being separated from the first semiconductor layer; and a passivation layer on the back surface of the semiconductor substrate, the passivation layer covering at least a portion of the first semiconductor layer and at least a portion of the second semiconductor layer, wherein, the passivation layer includes impurities.

The first semiconductor layer and the second semiconductor layer may each include a doping region having a doping concentration that is higher than a doping concentration of the semiconductor substrate. And, in one embodiment of the present invention, the second semiconductor layer is at a height different from the first semiconductor layer by a recess portion of the back surface.

The recess portion may be one of a plurality of recess portions of the back surface, the recess portions being spaced apart from each other. Each of the recess portions may include sides and a bottom surface.

The first semiconductor layer may be at the bottom surface of each of the recess portions, and the second semiconductor layer may be between the recess portions on the back surface of the semiconductor substrate.

The passivation layer may include group III metal elements.

The passivation layer may include a metal oxide or a metal nitride. Further, the metal oxide may include an aluminum oxide, or the metal nitride may include an aluminum nitride.

The first semiconductor layer may be formed by implanting and diffusing the group III metal elements by laser beam irradiation in a state in which the first semiconductor layer is covered with the passivation layer.

The solar cell may further include a first electrode on the passivation layer, the first electrode being coupled to the first semiconductor layer; and a second electrode on the passivation layer, the second electrode being coupled to the second semiconductor layer, and spaced apart from the first electrode.

The solar cell may further include a second conductive type third semiconductor layer on a front surface of the semiconductor substrate; and an anti-reflective layer on the third semiconductor layer.

The third semiconductor layer and the anti-reflective layer may have a textured surface.

A method of manufacturing a solar cell according to an exemplary embodiment of the present invention includes forming a second semiconductor layer by implanting and diffusing first impurities into a back surface of a semiconductor substrate; forming a recess portion on the back surface of the semiconductor substrate by removing a part of the second semiconductor layer and a part of the back surface of the semiconductor substrate; forming a passivation layer having second impurities on the back surface of the semiconductor substrate, the passivation layer covering at least a portion of the second semiconductor layer and at least a portion of the recess portion; and forming the first semiconductor layer by implanting and diffusing the second impurities into the semiconductor substrate by irradiating a laser beam to a portion corresponding to the recess portion in the passivation layer.

The implanting and diffusing of the first impurities may be performed using a furnace heat treatment process.

After the second semiconductor layer is formed, a mask layer having an opening may be formed on the second semiconductor layer, and a part of the second semiconductor layer exposed by the opening may be removed by wet-etching.

The recess portion may be formed by wet-etching a portion of the semiconductor substrate exposed by the opening part; and the mask layer may be removed after the recess portion is formed.

The passivation layer may include an aluminum oxide or an aluminum nitride.

The method may further include when the second semiconductor layer is formed, concurrently forming a third semiconductor layer by implanting and diffusing the first impurities into the front surface of the semiconductor substrate.

The method may further include forming an anti-reflective layer on the third semiconductor layer.

The method may further include after the first semiconductor layer is formed, forming a first electrode coupled to the first semiconductor layer on the passivation layer; and forming a second electrode coupled to the second semiconductor layer.

The first electrode and the second electrode may be concurrently formed by a screen printing method.

According to an aspect of the exemplary embodiments, it is possible to simplify the process of manufacturing a solar sell since the process of forming the first semiconductor layer and the second semiconductor layer does not need to be repeatedly performed, and it is possible to reduce the process cost by reducing the furnace heat treatment process, which consumes a considerable amount of energy, to one time.

Further, according to an aspect of the exemplary embodiments, it is possible to relatively easily form the first semiconductor layer and prevent junction defects of the first semiconductor layer and the second semiconductor layer, by diffusing elements (e.g., uniformly diffusing group III elements).

### BRIEF DESCRIPTION OF THE DRAWINGS

FIG. 1A is a schematic diagram of a solar cell according to a first exemplary embodiment.

FIGS. 1B and 1C are partially enlarged diagrams of the solar cell shown in FIG. 1A.

FIG. 2 is a schematic diagram of a solar cell according to a second exemplary embodiment.

FIGS. 3A to 3G are schematic diagrams showing a manufacturing process of the solar cell according to exemplary embodiments.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. Further, it will be understood that when an element is referred to as being “on” another element, it can be directly on another element or intervening elements may be present therebetween.

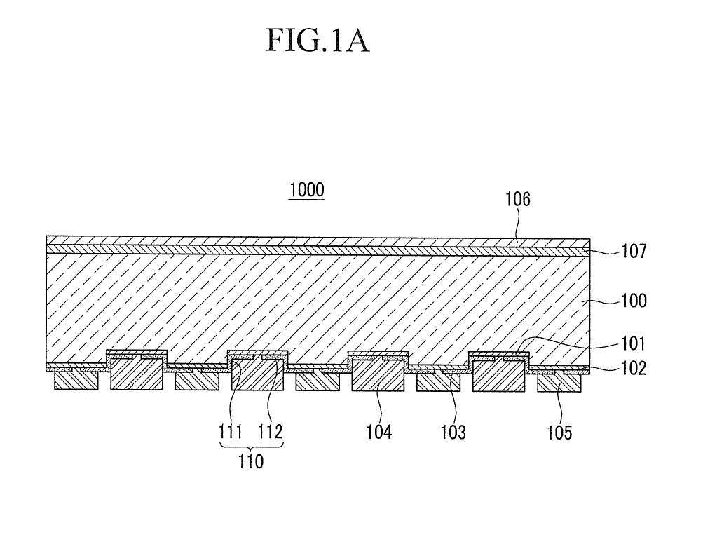

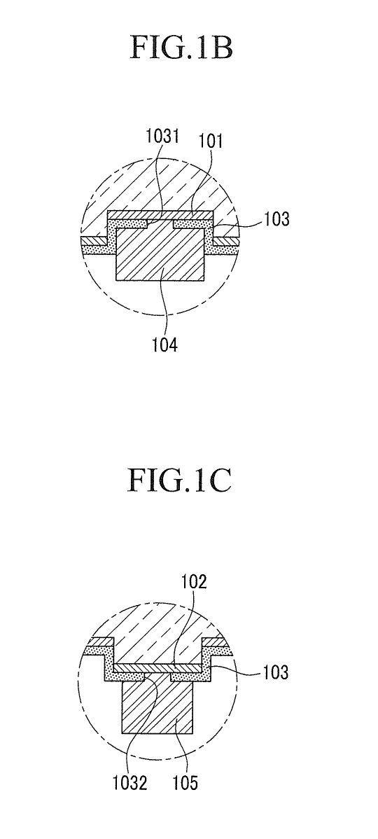

FIG. 1A is a schematic diagram of a solar cell according to a first exemplary embodiment, and FIGS. 1B and 1C are partially enlarged diagrams of the solar cell shown in FIG. 1A.

Referring to FIGS. 1A to 1C, a solar cell 1000 according to the first exemplary embodiment includes a semiconductor substrate 100, a first semiconductor layer 101 disposed on a back surface of the semiconductor substrate 100, a second semiconductor layer 102, a passivation layer 103, a first electrode 104, and a second electrode 105.

The semiconductor substrate 100 includes a front surface (light receiving surface) to which sunlight is incident and a back surface opposite to the front surface. A structure for collecting holes (e.g., a hole collector) and a structure for collecting electrons (e.g., an electron collector) may be formed on the back surface of the semiconductor substrate 100. The semiconductor substrate 100 has a first conductive type that, for example, may be made of p-type single crystal silicon or p-type polycrystalline silicon.

A plurality of segments of the first semiconductor layer 101 is disposed on the back surface of the semiconductor substrate 100 at a distance therebetween. In one embodiment of the present invention, the first semiconductor layer 101 has the first conductive type (e.g., conductivity type) that is the same as the semiconductor substrate 100 and may be configured to have a relatively high concentration p-type doping region (p+ layer) doped with, for example, an impurity having a higher concentration than that of the semiconductor substrate 100.

The segments of the first semiconductor layer 101 are disposed in parallel (or substantially in parrallel) to each other at the same height (or at substantially the same height).

In one embodiment of the present invention, the first semiconductor layer 101 may include a p+ back surface field (BSF) layer, which may reduce a leakage current and provide a relatively improved ohmic contact.

A plurality of segments of the second semiconductor layer 102 is disposed on the back surface of the semiconductor substrate 100 so as to be separated from the first semiconductor layer 101, while having a height difference from the first semiconductor layer 101. To this end, a plurality of recess portions 110 may be formed on the back surface of the semiconductor substrate 100. Each of the recess portions 110 includes sides 111 and a bottom surface 112. A height of the sides 111 may be set to be approximately 2 μm or less.

In one embodiment of the present invention, the first semiconductor layer 101 is at (e.g., contacts) the bottom surface 112 of the recess portions 110, and the second semiconductor layer 102 is on the back surface of the semiconductor substrate 100 at portions of the back surface where the recess portions 110 are not formed. That is, the second semiconductor layer 102 may be disposed on the back surface of the semiconductor substrate 100 between the recess portions 110.

The second semiconductor layer 102 has a second conductive type that is an opposite type to the first semiconductor layer 101 and may be configured to have a relatively high-concentration n-type doping region (n+ layer).

The passivation layer 103 may be at (e.g., formed over) the back surface of the semiconductor substrate 100, and may cover at least a portion of the first semiconductor layer 101 and at least a portion of the second semiconductor layer 102. The passivation layer 103 may cover the sides 111 of the recess portions 110, the bottom surfaces 112 of the recess portions 110 on which the first semiconductor layer 101 is formed, and the back surface (e.g., the whole back surface) of the semiconductor substrate 100 on which the second semiconductor layer 102 is formed. Side portions of the passivation layer 103 formed on the sides 111 of the recess portions 110 may serve as an insulating layer that insulates the first semiconductor layer 101 and the second semiconductor layer 102 from each other.

The passivation layer 103 may include impurities for forming the first semiconductor layer 101. For example, the passivation layer 103 may include group III metal elements as the impurities for forming the first semiconductor layer 101. Therefore, the passivation layer 103 may serve as a doping source of the first semiconductor layer 101.

In the manufacturing process of the solar cell 1000 described below, the first semiconductor layer 101 may be formed, for example, by a laser irradiation method. For example, when a specific portion of the passivation layer 103 is irradiated with a laser beam, the first semiconductor layer 101 is formed while the impurities included in the passivation layer 103 are implanted and diffused to the semiconductor substrate 100 by the high energy of the laser beam.

As described above, the passivation layer 103 may be, for example, a metal oxide type or a metal nitride type so as to implement insulating performance while serving as the doping source of the first semiconductor layer 101. For example, the passivation layer 103 may include any one of aluminum oxide or aluminum nitride.

The first semiconductor layer 101 and the second semiconductor layer 102 may be disposed at different heights due to the formation of the recess portions 110, such that it is possible to prevent the first semiconductor layer 101 and the second semiconductor layer 102 from being junctioned to each other in an undesired direction. The passivation layer 103 may also insulate the first semiconductor layer 101 and the second semiconductor layer 102 from each other to prevent (or substantialy prevent) junction defects. In addition, the passivation layer 103 may serve to facilitate the doping of the first semiconductor layer 101 and simplify the manufacturing process of the solar cell 1000.

In one embodiment of the present invention, the passivation layer 103 has a plurality of first via holes 1031 (see, e.g., FIG. 1B) that exposes a plurality of first via hole portions of the first semiconductor layer 101, and a plurality of first electrodes 104 is formed on the passivation layer 103 filling the first via holes 1031.

In one embodiment of the present invention, the passivation layer 103 has a plurality of second via holes 1032 (see, e.g., FIG. 1C) that exposes a plurality of second via hole portions of the second semiconductor layer 102 and a plurality of second electrodes 105 is formed on the passivation layer 103 filling the second via holes 1032.

The first electrodes 104 serve as a current collector of the first semiconductor layer 101 and the second electrodes 105 serve as a current collector of the second semiconductor layer 102. The first electrodes 104 and the second electrodes 105 may include a metal, for example, aluminum (Al), silver (Ag), or the like, and may be disposed at a distance from each other so as not to be short-circuited with each other. The first electrodes 104 may be coupled (e.g., connected) to one another (e.g., at an end or an edge of the semiconductor substrate 100) and the second electrodes 105 may also be coupled (e.g., connected) to one another (e.g., at an end or an edge of the semiconductor substrate 100).

When the solar cell 1000 receives sunlight, electrons having (−) charges and holes having (+) charges are generated on the semiconductor substrate 100. The holes are transferred to the first electrodes 104 via the first semiconductor layer 101 and the electrons are transferred to the second electrodes 105 via the second semiconductor layer 102. The first electrodes 104 and the second electrodes 105 may be coupled (e.g., connected) to external loads (e.g., resistors) to supply power generated in the solar cell 1000 to the external loads.

An anti-reflective layer 106 may be disposed on the front surface of the semiconductor substrate 100 to which sunlight is incident. The anti-reflective layer 106 serves to reduce light reflection loss on the surface of the solar cell 1000 and increase selectivity of a specific wavelength region. The anti-reflective layer 106 may be configured to include, for example, a stacked layer of a silicon oxide layer and a silicon nitride layer of which the refractive indexes are different.

A third semiconductor layer 107 may be formed between the semiconductor substrate 100 and the anti-reflective layer 106. The third semiconductor layer 107 may have a second conductive type that is the same as the second semiconductor layer 102 and may be configured to have a relatively high-concentration n-type doping region (n+ layer). In one embodiment of the present invention, the third semiconductor layer 107, which may be a front surface field layer, serves to increase an opening voltage by reducing charge recombination and reducing resistance loss. The third semiconductor layer 107 may concurrently be formed in the same process as the second semiconductor layer 102.

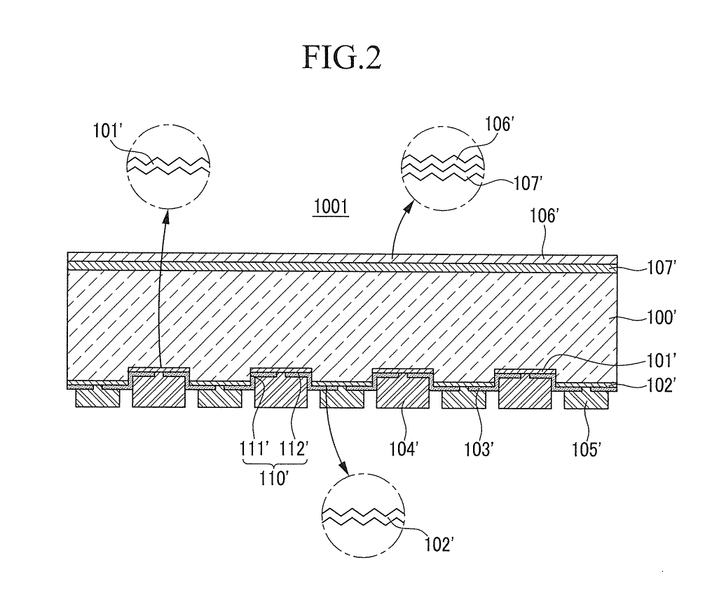

FIG. 2 is a schematic diagram of a solar cell according to a second exemplary embodiment.

Referring to FIG. 2, a solar cell 1001 according to the second exemplary embodiment is formed to have the same (or substantially the same) structure as the solar cell according to the first exemplary embodiment as described above except that a front surface and a back surface of a semiconductor substrate 100′ are textured. Thus for convenience, FIG. 2 uses similar reference numerals as in FIG. 1A to refer to similar or corresponding elements (e.g., XX is similar to XX′), and descriptions of certain aspects of the solar cell 1001 are given by way of reference to the solar cell 1000 and will be omitted herein.

Surface texturing means that the surface of the semiconductor substrate 100′ has a texture, for example the surface of the semiconductor substrate may have a pyramid, trapazoidal, jagged, ridged, or rugged shape.

The front surface texturing of the semiconductor substrate 100′ serves to increase absorption of sunlight by increasing (e.g., expanding) a surface area, and serves to increase a current of the solar cell 1001 by reducing reflectivity, thereby increasing efficiency. The back surface texturing of the semiconductor substrate 100′ serves to induce (or improve) internal reflection to make a passage of incident light relatively long, thereby increasing an opportunity that sunlight will be absorbed in the semiconductor substrate 100′.

In one embodiment of the present invention, a third semiconductor layer 107′ and an anti-reflective layer 106′ are disposed on the front surface of the semiconductor substrate 100′ of which the surface is textured. Further, a first semiconductor layer 101′, a second semiconductor layer 102′, a passivation layer 103′, a plurality of first electrodes 104′, and a plurality of second electrodes 105′ may be disposed on the back surface of the semiconductor substrate 100′ of which the surface is textured.

Additionally, the solar cell 1001 may include a plurality of recess portions 110′ formed on the back surface of the semiconductor substrate 100′. Each of the recess portions includes sides 111′ and a bottom surface 112′.

Next, a manufacturing method of the aforementioned solar cell will be described.

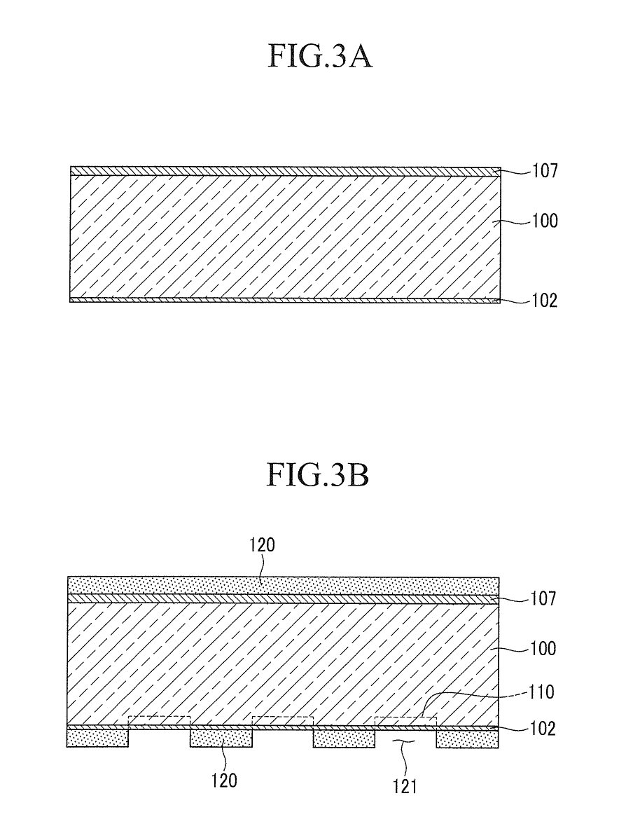

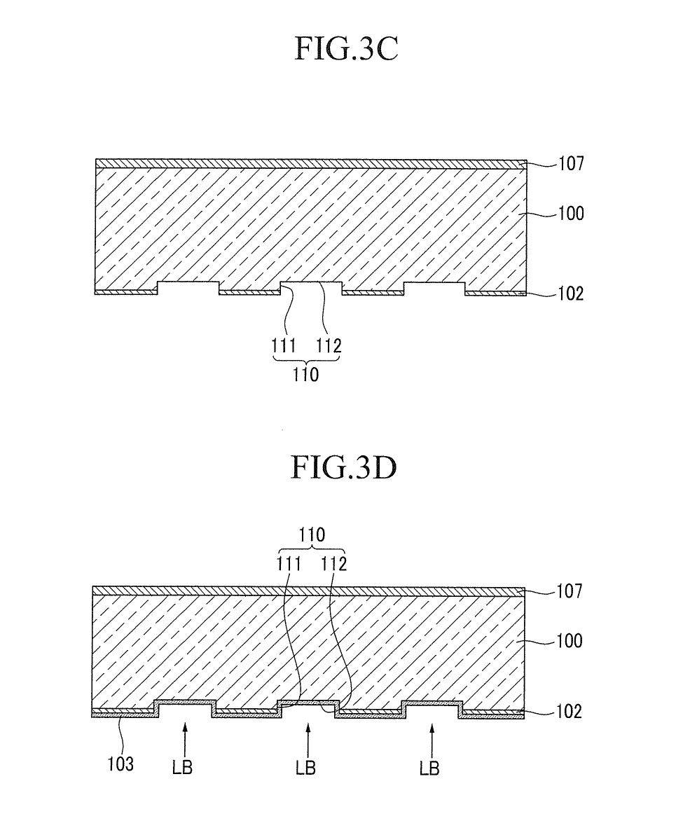

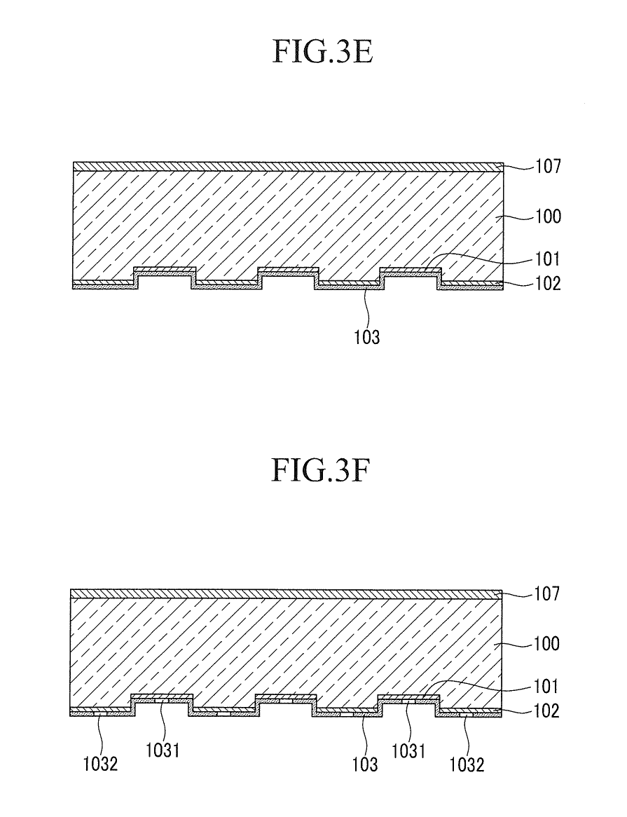

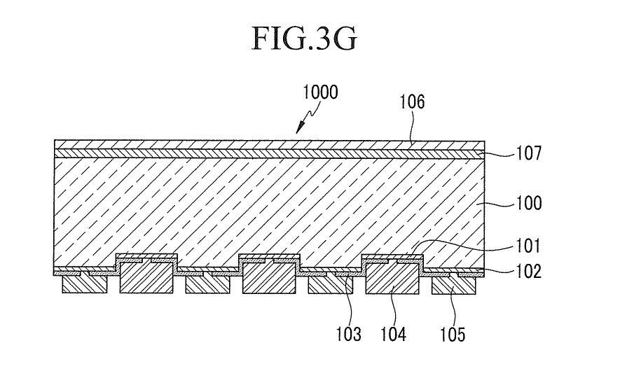

FIGS. 3A to 3G are schematic diagrams showing a manufacturing process of the solar cell according to the exemplary embodiments of the present invention.

The following description of the manufacturing process of a solar cell is made in connection with the schematic diagram showing the solar cell according to exemplary embodiments of the present invention, and it is to be understood that aspects of the present invention are not limited to the manufacturing process of the solar cell according to the embodiments depicted in FIGS. 3A-3G, but, on the contrary, because other embodiments may have much of the same (or similar) structure as the described exemplary embodiments, the description of the manufacturing process is intended to cover, for example, a manufacturing process of the solar cell according to other embodiments within the sprit and scope of the present invention.

Referring to FIG. 3A, the first conductive type semiconductor substrate 100, for example, a p-type silicon substrate is prepared. The surface of the semiconductor substrate 100 may be etched with, for example, an acid solution or an alkali solution. When the substrate 100 is etched, a cutting process of the semiconductor substrate 100 may be omitted, thus preventing (or substantially preventing) cutting damage to the surface of the semiconductor substrate from occurring and mechanical strength may be increased.

Thereafter, the front surface and the back surface of the semiconductor substrate 100 may be subjected to a texturing process. For the surface texturing, a mechanical method using a micro diamond blade and a chemical method using plasma, an anisotropic etching solution, or an anisotropic etching solution, or the like, may be used.

Thereafter, the third semiconductor layer 107 (high concentration n type doping region) and the second semiconductor layer 102 (high concentration n type doping region) may be formed (or concurrently formed) by implanting and diffusing first impurities (e.g., group V impurities) into (or all over) the front surface and the back surface of the semiconductor substrate 100. In one embodiment of the present invention, phosphorous oxychloride (POCl₃) may be used as a doping source and a diffusion (doping) may be performed in the high temperature process, for example a high temperature process of approximately 900° C. or more, in a furnace.

Referring to FIG. 3B, a mask layer 120 may be formed on the third semiconductor layer 107 and the second semiconductor layer 102. In one embodiment of the present invention, the mask layer 120 covers the whole (or substantially the whole) third semiconductor layer 107 and a first portion of the second semiconductor layer 102. The mask layer 120 may expose a second portion of the second semiconductor layer 102 by forming a plurality of opening parts 121 on the second semiconductor layer 102. The mask layer 120 may be formed by a screen printing method having a simple process and a low process cost, and may be made of a resin.

The second portion of the second semiconductor layer 102 exposed by the opening parts 121 of the mask layer 120 may be removed using, for example, a first etching solution. Further, a portion of the semiconductor substrate 100 exposed by the opening parts 121 of the mask layer 120 may be removed using, for example, a second etching solution, thereby forming the recess portions 110. The first etching solution may be an HNA solution that is a mixture of hydrofluoric acid (HF), nitric acid (HNO₃), and acetic acid (CH₃COOH), and the second etching solution may be a hydrofluoric acid (HF) solution.

After the recess portions 110 are formed, the mask layer 120 is removed. The state in which the mask layer 120 is removed is shown in FIG. 3C. Referring to FIG. 3C, the recess portions 110 each include the sides 111 and the bottom surface 112. In one embodiment of the present invention, the height of the sides 111 is set to be at approximately 2 μm.

Referring to FIG. 3D, the passivation layer 103 may be deposited over the back surface of the semiconductor layer 100 on which the second semiconductor layer 102 and the recess portions 110 are formed. The passivation layer 103 may be formed on the surface of the second semiconductor layer 102 and over the sides 111 and the bottom surfaces 112 of the recess portions 110.

The passivation layer 103 may include second impurities, for example, group III metal elements, and may be a metal oxide type or a metal nitride type to have insulating properties. The passivation layer 103 may include any one of aluminum oxide or aluminum nitride. If the passivation layer includes the aluminum oxide, an aluminum oxide layer may be formed, for example, by blowing oxygen at the time of depositing aluminum. The passivation layer 103 may serve as the insulating layer that insulates the first semiconductor layer 101 and the second semiconductor layer 102 from each other while serving as the deposition source of the first semiconductor layer.

In one embodiment of the present invention, only portions of the passivation layer 103 corresponding to the recess portions 110 are irradiated with a laser beam LB. A group III metal element, which may be included in the passivation layer 103, for example, aluminum (Al), may be implanted and diffused into the semiconductor substrate 100 by a high energy of a laser beam LB. Thereby, a portion at (e.g., contacting) the bottom surfaces 112 of the recess portions 110 in the semiconductor substrate 100 may be provided with the first semiconductor layer 101 (e.g., a high concentration p-type doping region) (see FIG. 3E).

Referring to FIGS. 3D and 3E, the doping concentration of the first semiconductor layer 101 may be controlled according to the conditions of the laser beam LB. For example, the strength of the laser beam LB my be increased by controlling a focal distance of the laser beam LB, thereby increasing the amount of impurities (e.g., group III impurities) implanted into the semiconductor substrate 100. In one embodiment of the present invention, the laser beam LB is a green laser beam of a wavelength of 532 nm.

The focal distance of the laser beam LB is inversely proportional to the strength of the laser beam LB. As the strength of the laser beam LB is increased, the doping concentration of the first semiconductor layer 101 is increased and thus, the surface resistance of the first semiconductor layer 101 may be reduced. The type and focal distance, or the like, of the laser beam may be variously controlled according to specifications of a laser apparatus.

In one embodiment of the present invention, only the region to which the laser beam (LB) is irradiated is uniformly doped with the impurities (e.g., the high concentration group III elements) by using the passivation layer 103 and the laser doping method. The effect is due to the high energy characteristics of the laser beam (LB), and the semiconductor substrate 100 may be uniformly doped with, for example, the group III metal element included in the passivation layer 103 by the high energy of the laser beam (LB).

In one embodiment of the present invention, in order to effectively restrict the irradiated region of the laser beam (LB), a light shielding mask (not shown) may be disposed between the back surface of the semiconductor substrate 100 and a laser light source (not shown). The light shielding mask serves to shield light so that the laser beam (LB) is not irradiated (or is substantially not irradiated) to a region other than the recess portions 110.

Referring to FIG. 3F, the first via holes 1031 and the second via holes 1032 may be formed on the passivation layer 103. The first via holes 1031 may be formed to expose the first via hole portions of the first semiconductor layer 101 and the second via holes 1032 may be formed to expose the second via hole portions of the second semiconductor layer 102. The first via holes 1031 and the second via holes 1032 may be formed by a general patterning method such as laser irradiation or photolithography.

Referring to FIGS. 3F and 3G, the first electrodes 104 and the second electrodes 105 may be formed (e.g., concurrently formed) by screen printing a metal paste on the passivation layer 103. The first electrodes 104 may be coupled (e.g., connected) to the first semiconductor layer 101 through the first via holes 1031 and the second electrodes 105 may be coupled (e.g., connected) to the second semiconductor layer 102 through the second via holes 1032. The first electrodes 104 and the second electrodes 105 are disposed at a distance from each other so as not to be short-circuited with each other.

Further, the anti-reflective layer 106 may be formed by stacking a silicon oxide layer and a silicon nitride layer on the third semiconductor layer 107.

A furnace heat treatment process for forming the second semiconductor layer 102 before forming the first electrodes 104 and the second electrodes 105, the printing process for forming the mask layer 120, a wet etching process for forming the recess portions 110, and a deposition process for forming the passivation layer 103 are performed only once, such that the manufacturing process of, for example, the solar cell 1000 according to the exemplary embodiments may be be simplified.

That is, since methods for forming the first semiconductor layer 101 and the second semiconductor layer 102 are not the same, the process for forming the first semiconductor layer 101 and the second semiconductor layer 102 does not need to be performed twice, such that the whole process may be be simplified. In particular, the furnace heat treatment process, which consumes a considerable amount of energy, is reduced to one time and, thus, the process cost of the solar cell 1000 may be reduced.

Further, the first semiconductor layer 101 may be relatively easily formed by diffusing (e.g., uniformly diffusing) elements, (e.g., the group III elements) that are not easily diffused by using the passivation layer 103 and the laser beam (LB). In addition, the junction defects between the first semiconductor layer 101 and the second semiconductor layer 102 may be effectively prevented (or substantially prevented) by using the height difference between the first semiconductor layer 101 and the second semiconductor layer 102, the recess portion 110, and the passivation layer 103 having the insulating function.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

Description of Some of the Reference Numerals

| | |
|---|---|
| 1000, 1001: Solar cell | 100, 100′: Semiconductor substrate |
| 101, 101′: First semiconductor layer | 102, 102′: Second semiconductor |
| | layer |
| 103, 103′: Passivation layer | 104, 104′: First electrode |
| 105, 105′: Second electrode | 106, 106′: Anti-reflective layer |
| 107, 107′: Third semiconductor layer | 110, 110′: Recess portion |
| 111, 111′: Side | 112, 112′: Bottom surface |
| 120: Mask layer | |

What is claimed is:

1. A solar cell comprising:
a first conductive type semiconductor substrate;
a first conductive type first semiconductor layer on a back surface of the semiconductor substrate;
a second conductive type second semiconductor layer on the back surface of the semiconductor substrate at a height different from the first semiconductor layer, the second semiconductor layer being separated from the first semiconductor layer; and
a passivation layer on the back surface of the semiconductor substrate, the passivation layer covering at least a portion of the first semiconductor layer and at least a portion of the second semiconductor layer, wherein the passivation layer comprises impurities.

2. The solar cell of claim 1, wherein
the first semiconductor layer and the second semiconductor layer each comprise a doping region having a doping concentration that is higher than a doping concentration of the semiconductor substrate; and
the second semiconductor layer is at a height different from the first semiconductor layer by a recess portion of the back surface.

3. The solar cell of claim 2, wherein
the recess portion comprises one of a plurality of recess portions of the back surface, the recess portions being spaced apart from each other; and
each of the recess portions comprises sides and a bottom surface.

4. The solar cell of claim 3, wherein
the first semiconductor layer is at the bottom surface of each of the recess portions, and
the second semiconductor layer is between the recess portions on the back surface of the semiconductor substrate.

5. The solar cell of claim 1, wherein
the passivation layer comprises group III metal elements.

6. The solar cell of claim 5, wherein
the passivation layer comprises a metal oxide and a metal nitride.

7. The solar cell of claim 6, wherein
the metal oxide comprises an aluminum oxide, or the metal nitride comprises an aluminum nitride.

8. The solar cell of claim 5, wherein
the first semiconductor layer is formed by implanting and diffusing the group III metal elements by laser beam irradiation in a state in which the first semiconductor layer is covered with the passivation layer.

9. The solar cell of claim 1, further comprising:
a first electrode on the passivation layer, the first electrode being coupled to the first semiconductor layer; and
a second electrode on the passivation layer, the second electrode being coupled to the second semiconductor layer, and spaced apart from the first electrode.

10. The solar cell of claim 9, further comprising:
a second conductive type third semiconductor layer on a front surface of the semiconductor substrate; and
an anti-reflective layer on the third semiconductor layer.

11. The solar cell of claim 10, wherein
the third semiconductor layer and the anti-reflective layer have a textured surface.

12. A method of manufacturing a solar cell, the method comprising:
forming a second semiconductor layer by implanting and diffusing first impurities into a back surface of a semiconductor substrate;
forming a recess portion on the back surface of the semiconductor substrate by removing a part of the second semiconductor layer and a part of the back surface of the semiconductor substrate;
forming a passivation layer comprising second impurities on the back surface of the semiconductor substrate, the passivation layer covering at least a portion of the second semiconductor layer and at least a portion of the recess portion; and
forming the first semiconductor layer by implanting and diffusing the second impurities into the semiconductor substrate by irradiating a laser beam to a portion corresponding to the recess portion in the passivation layer.

13. The method of claim 12, wherein
the implanting and diffusing of the first impurities is performed using a furnace heat treatment process.

14. The method of claim 12, wherein
after the second semiconductor layer is formed, a mask layer having an opening is formed on the second semiconductor layer, and
a part of the second semiconductor layer exposed by the opening is removed by wet-etching.

15. The method of claim 14, wherein
the recess portion is formed by wet-etching a portion of the semiconductor substrate exposed by the opening part, and
the mask layer is removed after the recess portion is formed.

16. The method of claim 12, wherein
the passivation layer comprises an aluminum oxide or an aluminum nitride.

17. The method of claim 12, further comprising:
when the second semiconductor layer is formed, concurrently forming a third semiconductor layer by implanting and diffusing the first impurities into the front surface of the semiconductor substrate.

18. The method of claim 17, further comprising
forming an anti-reflective layer on the third semiconductor layer.

19. The method of claim 12, further comprising
after the first semiconductor layer is formed, forming a first electrode coupled to the first semiconductor layer on the passivation layer, and
forming a second electrode coupled to the second semiconductor layer.

20. The method claim 19, wherein
the first electrode and the second electrode are concurrently formed by a screen printing method.
